(19) United States
(12) Patent Application Publication
(10) Pub. No.: US 2025/0083594 A1
(43) Pub. Date: Mar. 13, 2025

(54) Cooling and Heating System for a Vehicular Messaging System such as a Digital License Plate

(71) Applicant: Andrew L Butler, Linden, NJ (US)

(72) Inventor: Andrew L Butler, Linden, NJ (US)

(21) Appl. No.: 18/883,284

(22) Filed: Sep. 12, 2024

Related U.S. Application Data
(60) Provisional application No. 63/582,602, filed on Sep. 14, 2023.

(51) Int. Cl. B60Q 1/50; G02F 1/1333; G09F 9/30; G09F 21/04; H05K 7/20

(52) U.S. Cl. CPC B60Q 1/5035; G09F 9/30; G09F 21/048; H05K 7/20163; H05K 7/20972; G02F 1/133385

(57) ABSTRACT

A cooling and heating system for a vehicular messaging system such as a digital license plate has a micro-air pump inconspicuously mounted on a vehicle, utilized to suction cool or heated air, through an insulated air line or hose, from the occupied area of a vehicle into the enclosure of a digital license plate or vehicular messaging system, in order to maintain safe and continuous operating temperatures.

### RELATED APPLICATION

This application claims the benefit of application. Ser. No. 63/582,502 filed on Sep. 14, 2023 and application. Ser. No. 63/664,878 filed on Jun. 27, 2024.

### FIELD OF THE INVENTION

The present invention relates to the temperature control of digital license plates or like vehicular messaging systems.

### BACKGROUND OF THE INVENTION

Digital license plates or similar vehicular messaging panels and systems provide many different types of informational functions, including displaying advertisements, communicating information which prevents theft and enhances property recovery, showing weather and traffic information, etc. A digital license plate will replace the original license plate and serve as a platform for businesses to advertise their product/services in a geofenced manner. The digital license platform will also allow government entities to benefit from the platform by displaying amber/silver alerts, and other emergency messages that citizens should be aware of.

However, a critical problem associated with such messaging systems is that they tend to overheat during certain operating conditions. Their temperatures also can be affected by hot and cold weather conditions to which they are subjected.

Certain of these operating temperature conditions have been addressed in U.S. Pat. No. 10,446,068, the subject matter of which is incorporated by reference herein. Nonetheless, the present invention supplements and amplifies that which is disclosed in the patent.

### SUMMARY OF THE INVENTION

The present invention provides for a cooling and heating system for a digital license plate or vehicular messaging system or similar technologies. A micro-air pump or its equivalent is inconspicuously mounted on a vehicle and utilized to suction cool or heated air, through an insulated air line or hose, from the occupied area of a vehicle into the enclosure of a digital license plate or vehicular messaging system, in order to maintain safe and continuous operating temperatures. The digital license plate or vehicular messaging system could also be powered by solar technology or another energy sources. The air pump can be powered by the automobile car battery.

This invention contemplates the use of cellular technology, satellite technology, hot spot technology, blue tooth technology, artificial intelligence (AI) or similar technologies to transmit commands to the cooling and heating system of a digital license plate, vehicular messaging system and/or similar technologies. Additionally, such technologies may be utilized for other applicable purposes. For example, since hot spot technology may be utilized, the user may also use such technology to gain access to the internet and/or other compatible purposes.

The novel features which are considered as characteristic of the invention are set forth in particular in the appended claims. The invention, itself, however, both as to its design, construction and use, together with additional features and advantages thereof, are best understood upon review of the following detailed description with reference to the accompanying drawings.

### BRIEF DESCRIPTION OF THE DRAWINGS

FIG. 1 is a schematic of the operation of the system of the present invention.

FIG. 2 is a view of the rear end of a vehicle showing basic components of the system of the present invention on a digital license plate.

FIG. 3 is a view of the back side of a digital license plate showing basic components of the system of the present invention.

FIG. 4 is a schematic illustrating a secondary system designed to regulate cooling and heating of a digital license plate.

FIG. 5 is a schematic illustrating the manner in which the secondary system depicted in FIG. 4 is incorporated into the overall digital license plate system.

FIG. 6 shows how a standard license plate can be affixed to the rear of a vehicle capable of holding a digital license plate.

FIG. 7 illustrates how both a digital license plate and a standard license plate can be affixed to the rear of a vehicle.

FIG. 8 illustrates how a standard license plate can be affixed in an alternate configuration to the rear of a vehicle capable of holding a digital license plate.

FIG. 9 illustrates how both a digital license plate and a standard license plate can be affixed in an alternate configuration to the rear of a vehicle.

### DETAILED DESCRIPTION OF THE INVENTION

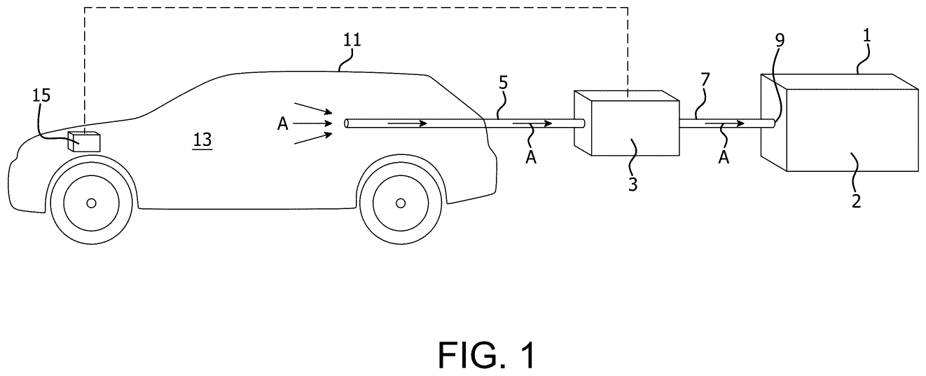

FIG. 1 is a partial schematic depicting the operation of the cooling and heating system for a digital license plate of the present invention. In order to ensure proper operational temperature of digital license plate enclosure 2 of digital license plate 1, micro-pump 3 suctions temperate air A from interior 13 of vehicle 11, through air line 5. Air A is then discharged from micro-pump 3 via discharge line 7 to inlet port 9 of digital license plate enclosure 2. In order to heat digital license plate enclosure 2, warm air A is drawn from vehicle 13. In order to cool digital license plate enclosure 2, cool air A is drawn from vehicle 13. Battery 15 of vehicle 11 can be used to power micro-pump 3.

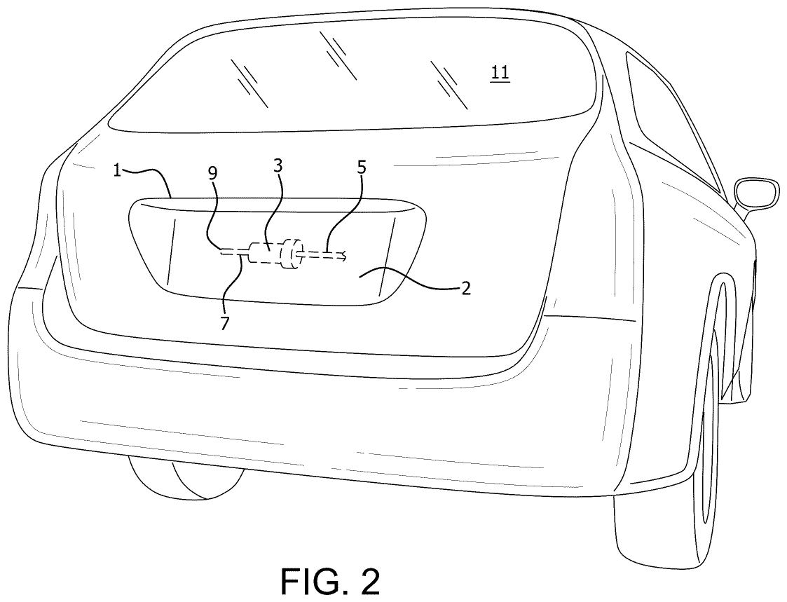

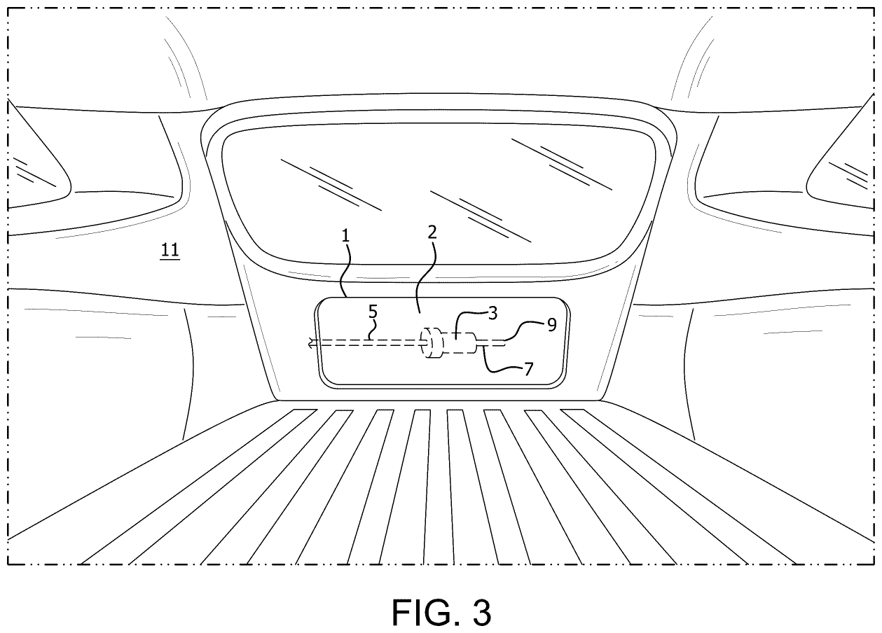

FIGS. 2 and 3 depict digital license plate 1 affixed to the rear of vehicle 13. In these FIGs. micro-pump 3, air line 5, and discharge line 7 are shown mounted on the back side of digital license plate enclosure 2 of a digital license plate 1.

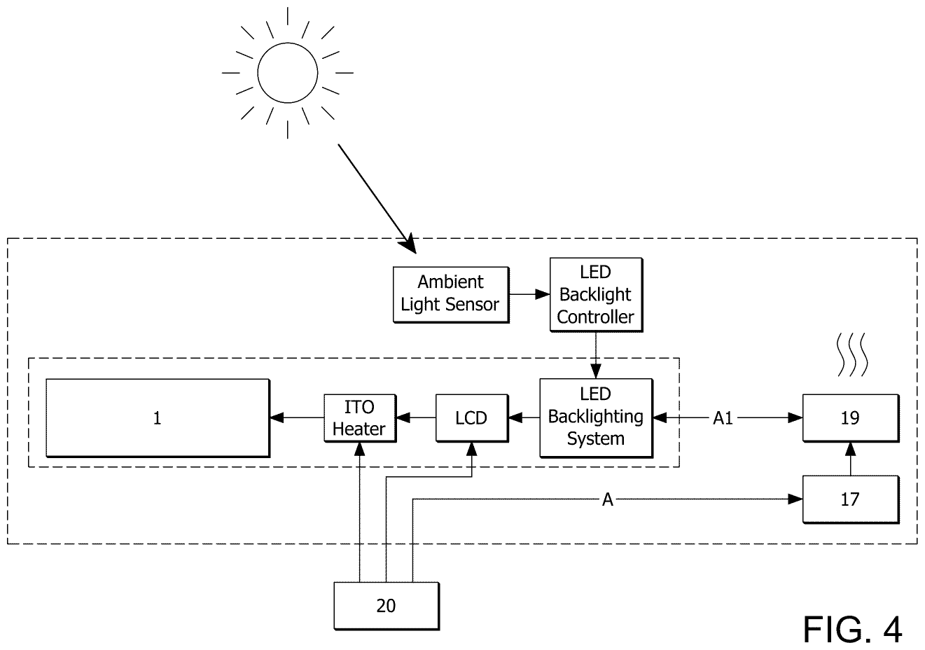

FIG. 4 illustrates an optional temperature regulating system, i.e. a secondary system which provides a means of additional cooling and heating of air from the vehicle cabin to digital license plate 1. Regulated air A is blown through axial fans 17 and across heatsinks attached to heatpipe 19. Heatpipe 19 carries refrigerant which creates a miniature HV/AC system. Optionally, a thermostat or similar thermostat technology may also be utilized in controlling temperature. This facilitates additional precise cooling and heating of effected air A1 to digital license plate 1, when needed.

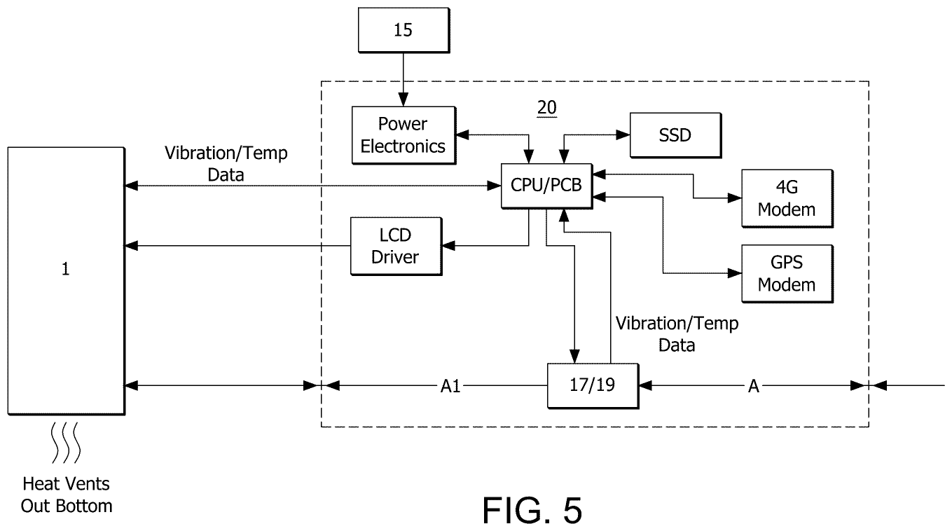

As is also seen in FIG. 4, air A1 is influenced by, among other factors, ambient light, LED backlight, and ITO (outside internet things) heat. The system's air to digital license plate is coordinated via other components which operate within the digital license plate system contained in control box 20, as depicted in FIG. 5.

The digital license plate system can also utilize a thermal electric cooler or similar technology, having a custom control scheme. This scheme also can regulate humidity and temperature and minimizes power consumption via a feedback loop.

The simple flow chart below further illustrates aspects of the present invention.

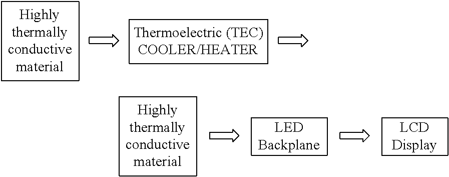

Thus, the system of the present invention represents technology which maintains temperatures that will allow a mobile digital display or similar technology and/or a vehicular messaging system to remain operable under all ambient conditions.

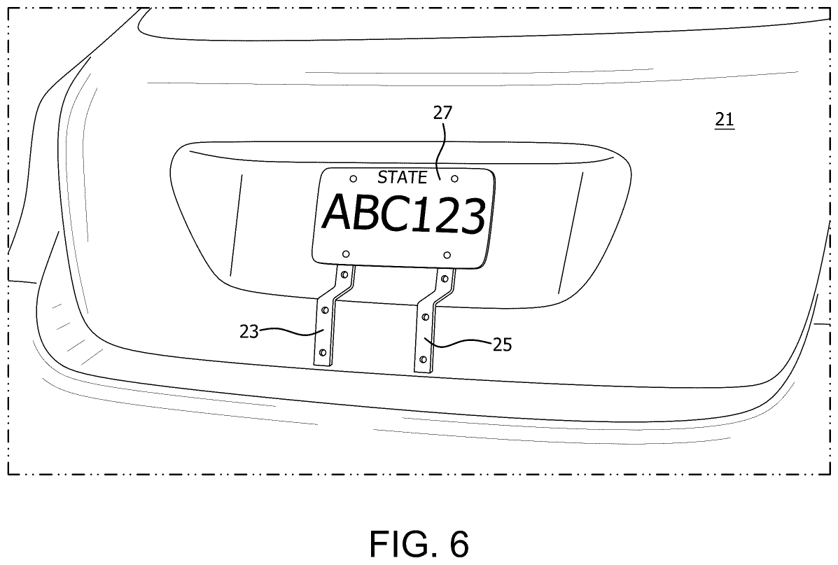

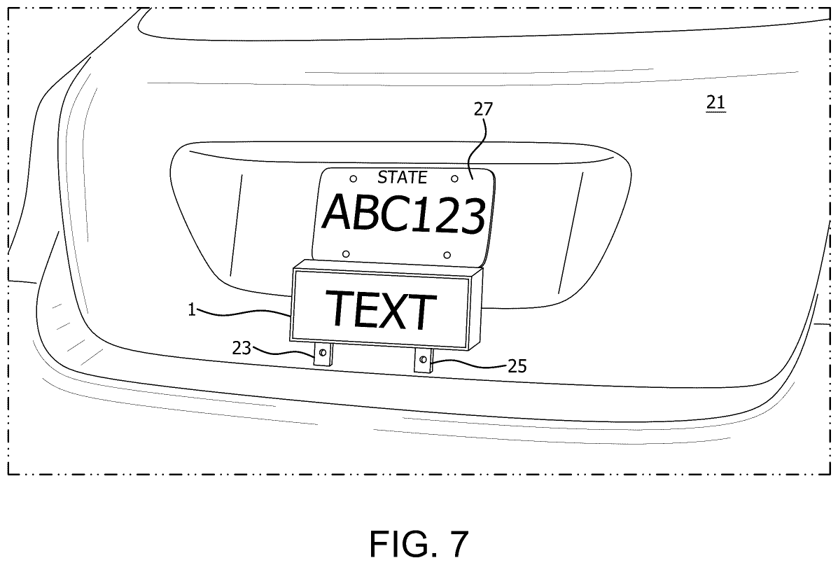

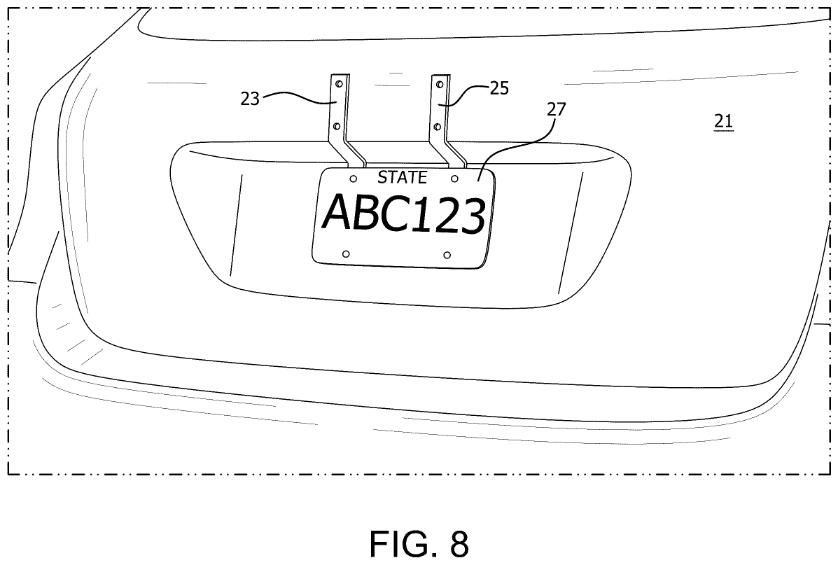

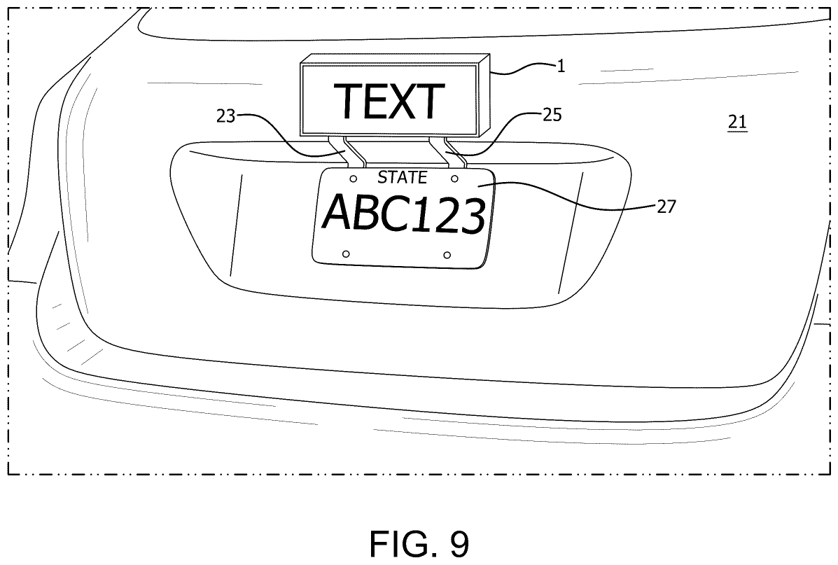

FIGS. 6, 7, 8 and 9 show how brackets 23 and 25 can be utilized to variably mount digital license plate 1 to the rear 21 of a vehicle in conjunction with a standard license plate 27, either directly below or directly above the license plate. Digital license plate 1 can also be retained by an appropriate holder which can be attached to a flexible neck, allowing the digital license plate the capability of being angled.

The digital display system will utilize a special/proprietary combination of UV/IR blocking films on anti-glare, impact resistant glass on the exterior surface on digital license plate 1. This will serve to block the majority of the solar loading experienced by ambient sunlight and prevent tainting of the glass. Internal condensation will be avoided by the use of optically bonded glass and a combination of humidity desiccants to absorb any humidity that may exist.

The system will use highly-efficient microLED backlighting system that will allow for a 10% drop in brightness output after 50,000 hours or more of usage lifespan. A High TNI (Twisted Nematic ITO (Indium Tin Oxide)) LCD Display will be employed to allow for very high temperature ratings and to prevent image distortion at those high temperatures.

The system will implement a custom control system that will monitor the vehicle speed via GPS, the ambient lighting, and the internal temperature of the system to determine how bright the backlighting system should be, and whether or not we need to perform an emergency shutdown.

In the event of an emergency shutdown, the cloud will be notified that a shutdown has occurred, as well as sending all the relevant telemetry data detailing the temperature/humidity conditions, vibrations, and any other process variable we wish to report. This will be used to train a custom neural network or any other AI based machine learning system to detect premature failures and warn the system and driver that a failure may occur and when.

The system will also have a custom RFID chip that law enforcements, tolls/highways, etc. will use to identify the digital license plate and receive information about the vehicle it is assigned to, including insurance, tax and journeys, so the plate can't be cloned.

The system will have proper shock and vibration prevention through the use of specialty rubber materials and automotive grade connectors.

### System Specifications

The following outlines some of the requirements for the manufacture of the digital digital license plate system of the present invention, designed to display advertisements, government and other messages from the license plate location or another location of a vehicle. The aim is to integrate advanced technology to ensure durability, functionality, and seamless integration with automotive systems.

### Project Overview

The system will be state-of-the-art, incorporating, but not limited to, the following high-level features:
4G LTE M1 Cellular Connectivity or similar/another technology.
Battery Voltage Monitoring/Protection
GPS Functionality or similar technology
Automotive-Grade Electronics or another grade of technology
Sunlight-Readable LCD/LED Display or similar technology
Vandal-Proof Protection and/or Impact resistant technologies
Compact Design (maximum thickness of 1 inch more or less)
Sealed to IP67/8/9 or other applicable standard to prevent water infiltration from pressure washing and car wash
Proper technology to prevent internal humidity buildup that may obscure visual advertisement
Method to defrost LCD panel in cold environments
Proper technology to minimize solar loading
Highly Efficient LED backlighting system or similar technology to minimize heat generation during peak daylight brightness or similar conditions
Automotive memory or other technology for Linux OS and Images
Proper electronics or other technologies to keep track of time locally (RTC), domestically and/or internationally
Custom mounting frame to simplify install and provide secure fixation

### Technical Requirements

### Hardware Specifications

### 1. Display:

LCD size of 12″×5″ (height/dimensions not final, TBD depending on what license plate character height that is authorized for use)
Automotive-grade LCD or other/similar technology that ensures readability under direct sunlight
Vandal-proof construction to withstand external damage.
Sealed to IP67/8/9 more or less to prevent water infiltration e.g., car washes and pressure washing events
Contains proper technology to prevent humidity inside LCD that may obscure advertisements/messages

### 2. Enclosure:

Total device thickness, including the enclosure will be one inch, more or less
Compliance with automotive standards and/or other applicable jurisdictions for durability and environmental conditions
Designed to work with all/or most vehicles
May contain top position for metal bar or another material that will contain legal license plate information (height TBD)
Sealed to IP67/8/9 and/or other applicable standards to prevent water infiltration from car washes and pressure washing events

### Software & Electrical Specifications

### 1. Operating System & Platform:

A Linux environment to support AWS Greengrass for cloud connectivity or similar technology
Development of control logic or another technology for managing the LCD and other peripheral devices
Support and development of low-level device drivers or another technology to interface with the Linux (or another technology) environment for reading sensors, obtaining GPS data or data from other technologies, etc.

### 2. Sensors & Peripherals:

Capability to report GPS data, temperature, humidity, vibrations, and other relevant sensors (full list of sensors TBD)
Sufficient memory to store 13,000 images (more or less) at any given time

### 3. Power Management:

A voltage monitoring system to prevent battery drainage
The system will be capable of downloading new images at a designated time of each day; which means the modem will wake up, ping the cloud, and download new images; the LCD or similar technology may not need to be on for this
Logic or other technology to detect vehicle ignition status (on/off) for power management and application logic control.
Ability to display advertisements or messages for around one hour more or less after the vehicle is turned off, while monitoring battery voltage to prevent drainage

### 4. Connectivity:

Integration of not limited to 4G LTE M1 cellular for reliable connectivity.
Shall utilize Velocity IoT's MFF2 Sim Card or similar ESIM/MFF2 footprint or another technology
GPS module or another technology for accurate realtime location tracking.
Does not need WAAS, DGPS, or RTK, fine with standard 10-20 meter accuracy

Certain novel features and components of this invention are disclosed in detail in order to make the invention clear in at least one form thereof. However, it is to be clearly understood that the invention as disclosed is not necessarily limited to the exact form and details as disclosed, since it is apparent that various modifications and changes may be made without departing from the spirit of the invention.

1. A cooling and heating system for a vehicular messaging system such as a digital license plate, said system comprising an air tight digital license plate enclosure, the license plate being externally mounted on a vehicle, said system comprising:
a micro-air pump affixed behind the digital license plate, said micro-air pump having a discharge line extending into an inlet port leading into the digital license plate enclosure;
an air intake line extending from the interior of the vehicle to the micro-air pump; wherein the micro-air pump suctions cool air via the air intake line from the interior of the vehicle, through the discharge line, to the inlet port and into the digital license plate enclosure to cool the digital license plate, and the micro-air pump suctions heated air via the air intake line from the interior of the vehicle, through the discharge line, to the inlet port and into the digital license plate enclosure to heat the digital license plate.

2. The system as in claim 1 wherein the air intake line is an insulated line.

3. The system as in claim 2 wherein the micro-air pump is powered by the vehicle's battery.

4. The system as in claim 1 wherein the digital license plate is affixed to the vehicle by brackets for receiving and securing multiple digital license plates and standard license plates.

5. The system as in claim 1 wherein the digital license plate comprises a combination of UV/IR blocking films on glass located on its exterior surface to block solar loading from ambient sunlight.

6. The system as in claim 1 further comprising a temperature regulating system having axial fans which blow cool or heated air from the interior of the vehicle across heatsinks attached to a refrigerant carrying heatpipe for precise cooling and heating of air to the digital license plate.
